(19) United States
(12) Patent Application Publication
(10) Pub. No.: US 2022/0320170 A1
(43) Pub. Date: Oct. 6, 2022

(54) FINGERPRINT RECOGNITION MODULE, FABRICATING METHOD THEREOF AND DISPLAY DEVICE

(71) Applicant: BOE Technology Group Co., Ltd., Beijing (CN)

(72) Inventors: Xiaoquan HAI, Beijing (CN); Lei WANG, Beijing (CN); Xuan LIANG, Beijing (CN); Yingzi WANG, Beijing (CN)

(21) Appl. No.: 17/419,835

(22) PCT Filed: Sep. 25, 2020
(86) PCT No.: PCT/CN2020/117904

§ 371 Date: Jun. 30, 2021

(51) Int. Cl. H01L 27/146

(52) U.S. Cl. CPC H01L 27/14627; H01L 27/14623; H01L 27/14685; H01L 27/14616; H01L 27/14678; H01L 24/32

(57) ABSTRACT

The fingerprint recognition module includes: a base substrate; an image sensing layer including sensors on the base substrate; a collimating optical layer on incident sides of the sensors and including light transmitting holes formed in one-to-one correspondence with part of the sensors, an orthographic projection of each of the light transmitting holes on the base substrate being in an orthographic projection of a corresponding sensor; and a light guiding layer on a side of the collimating optical layer facing away from the sensors and including microlenses. An orthographic projection of each of the microlenses on the base substrate completely covers orthographic projections of one of the light transmitting holes and at least two sensors, and each microlens is configured to converge light rays reflected by a finger and then transmit the converged light rays to the one sensor that it covers through the one light transmitting hole that it covers.

### CROSS REFERENCE TO RELATED APPLICATIONS

This application is a national phase entry under 35 U.S.C. § 371 of International Application No. PCT/CN2020/117904, filed on Sep. 25, 2020, the entire content of which is incorporated herein by reference.

### FIELD

The present disclosure relates to the technical field of display, in particular to a fingerprint recognition module, a method for fabricating the fingerprint recognition module, and a display device.

### BACKGROUND

With the high-speed development of the information industry, the biometric recognition technology has been more widely used, and in particular, since fingerprints of different users are different and help to confirm user identities, the fingerprint recognition technology has been widely used in various fields like mobile terminals, smart homes, etc., to guarantee security of user information.

Optical fingerprint recognition is one of the means to achieve fingerprint recognition. The principle of optical fingerprint recognition is as follows: when a finger is placed on a display product, emitted light from a light source of the display product strikes the locations of valleys and ridges of the finger, and is reflected by the valleys and ridges of the finger to enter an optical fingerprint recognition device included in the display product. Since the locations of the valleys and the ridges reflect different light intensities, a photosensitive device generates different electrical signals depending on the differences of the reflected light intensities, thereby achieving fingerprint recognition.

### SUMMARY

In one aspect, embodiments of the present disclosure provide a fingerprint recognition module, including:

a base substrate;

an image sensing layer including a plurality of sensors located on the base substrate;

a collimating optical layer located on incident sides of the plurality of sensors and including a plurality of light transmitting holes formed in one-to-one correspondence with part of the sensors; an orthographic projection, on the base substrate, of each of the light transmitting holes being located in an orthographic projection, on the base substrate, of a sensor corresponding to the each light transmitting hole; and

a light guiding layer located on a side of the collimating optical layer facing away from the plurality of sensors and including a plurality of microlenses; an orthographic projection of each of the microlenses on the base substrate completely covers orthographic projections, on the base substrate, of a respective one of the light transmitting holes and at least two of the sensors, and each of the microlenses is configured to converge light rays reflected by a finger and then transmit the converged light rays to one of the at least two sensors that it covers through the respective one light transmitting hole that it covers.

Optionally, in the fingerprint recognition module provided by the embodiments of the present disclosure, centers of the orthographic projections of the microlenses on the base substrate coincide with centers of orthographic projections of the light transmitting holes covered completely by the microlenses.

Optionally, in the fingerprint recognition module provided by the embodiments of the present disclosure, the collimating optical layer includes a first light shading layer, a first light transmitting layer, a second light shading layer, and a second light transmitting layer disposed in a stacked manner. The first light shading layer is adjacent to the plurality of sensors, and the second light transmitting layer is adjacent to the plurality of microlenses.

A distance, in a direction perpendicular to the base substrate, between the second light shading layer and a layer where the plurality of microlenses are located is smaller than or equal to a focal length of each of the microlenses, and a ratio of a thickness of the second light transmitting layer to a thickness of the first light transmitting layer is greater than or equal to 1 and smaller than or equal to 10.

Optionally, in the fingerprint recognition module provided by the embodiments of the present disclosure, the light transmitting holes include: first light transmitting holes located in the first light shading layer, and second light transmitting holes located in the second light shading layer.

Orthographic projections of the first light transmitting holes on the base substrate coincide completely with orthographic projections of the second light transmitting holes on the base substrate.

Optionally, in the fingerprint recognition module provided by the embodiments of the present disclosure, the collimating optical layer further includes: a third light shading layer located between the second light transmitting layer and the layer where the plurality of microlenses are located.

An orthographic projection of the third light shading layer on the base substrate covers gaps between the microlenses and overlaps with edge areas of the orthographic projections of the plurality of microlenses on the base substrate.

Optionally, in the fingerprint recognition module provided by the embodiments of the present disclosure, the light transmitting holes include: first light transmitting holes located in the first light shading layer, and second light transmitting holes located in the second light shading layer.

Orthographic projections of the second light transmitting holes on the base substrate lie in orthographic projections of the first light transmitting holes on the base substrate.

Optionally, in the fingerprint recognition module provided by the embodiments of the present disclosure, a thickness of each of the first light shading layer, the second light shading layer, and the third light shading layer in the direction perpendicular to the base substrate is greater than 0 μm and smaller than or equal to 3 μm.

Optionally, in the fingerprint recognition module provided by the embodiments of the present disclosure, materials of the first light shading layer, the second light shading layer, and the third light shading layer are a black matrix material, molybdenum oxide, aluminum oxide, or chromium metal.

Optionally, in the fingerprint recognition module provided by the embodiments of the present disclosure, the first light transmitting layer and/or the second light transmitting layer are/is multiplexed as a light filter layer.

Optionally, the fingerprint recognition module provided by the embodiments of the present disclosure further includes: a light filter layer located between the layer where the plurality of microlenses are located and the collimating optical layer, or between the collimating optical layer and a layer where the plurality of sensors are located, or between the light shading layer and the light transmitting layer adjacent thereto.

Optionally, in the fingerprint recognition module provided by the embodiments of the present disclosure, the light filter layer is configured to filter out ambient light above 600 mm.

Optionally, in the fingerprint recognition module provided by the embodiments of the present disclosure, the image sensing layer, the collimating optical layer, the light guiding layer, and the light filter layer are film layers arranged on the base substrate in a stacked manner.

Optionally, the fingerprint recognition module provided by the embodiments of the present disclosure further includes: an optical adhesive layer in contact with surfaces of sides of the plurality of sensors facing away from the base substrate.

In another aspect, embodiments of the present disclosure further provide a display device, including a display module, a fingerprint recognition module located on an opposite side of a display surface of the display module, and an adhesive layer located between the display module and the fingerprint recognition module.

The fingerprint recognition module is the fingerprint recognition module described above.

An orthographic projection of the adhesive layer on the display module is located in a frame area of the display module.

In another aspect, embodiments of the present disclosure provide a method for fabricating a fingerprint recognition module, including:

providing a base substrate; and

sequentially fabricating an image sensing layer including a plurality of sensors, a collimating optical layer, and a light guiding layer including a plurality of microlenses on the base substrate.

The collimating optical layer includes a plurality of light transmitting holes formed in one-to-one correspondence with part of the sensors, and orthographic projections of the light transmitting holes on the base substrate lie in orthographic projections of the sensors disposed corresponding thereto.

An orthographic projection of each of the microlenses on the base substrate completely covers orthographic projections of one of the light transmitting holes and at least two of the sensors, and each of the microlenses is configured to converge light rays reflected by a finger and then transmit the converged light rays to one sensor that it covers through the one light transmitting hole that it covers.

In another aspect, embodiments of the present disclosure provide a method for fabricating a fingerprint recognition module, including:

providing a first base substrate;

fabricating an image sensing layer including a plurality of sensors on the first base substrate;

providing a second base substrate;

fabricating a light filter layer, a collimating optical layer, and a light guiding layer including a plurality of microlenses on the second base substrate, the collimating optical layer including a plurality of light transmitting holes, and an orthographic projection of each of the microlenses on the second base substrate completely covers one of the light transmitting holes; and

attaching the second base substrate with the light filter layer, the collimating optical layer, and the plurality of microlenses to incident sides of the plurality of sensors by optical adhesive, such that the plurality of light transmitting holes are formed in one-to-one correspondence with part of the sensors after attachment, orthographic projections of the light transmitting holes on the second base substrate lie in orthographic projections of the sensors disposed corresponding thereto, and the orthographic projection of each of the microlenses on the second base substrate completely covers the orthographic projections of at least two of the sensors. Each of the microlenses is configured to converge light rays reflected by a finger and then transmit the converged light rays to the one sensor that it covers through the one light transmitting hole that it covers.

Optionally, in the method provided by the embodiments of the present disclosure, fabricating the light filter layer, the collimating optical layer, and the plurality of microlenses on the second base substrate includes:

fabricating a first light transmitting layer, a second light shading layer, and a second light transmitting layer in sequence on the second base substrate, the first light transmitting layer being multiplexed as the light filter layer, a thickness of the second light transmitting layer perpendicular to the second base substrate is smaller than or equal to a focal length of each of the microlenses to be fabricated, and the second light shading layer includes a plurality of second light transmitting holes;

fabricating the plurality of the microlenses on the second light transmitting layer, the orthographic projection of each of the microlenses on the second base substrate completely covers orthographic projections of one of the second light transmitting holes and at least two of the sensors; and

fabricating a first light shading layer on one side of the second base substrate facing away from the first light transmitting layer. The first light shading layer includes a plurality of first light transmitting holes which fully coincide with the plurality of second light transmitting holes in a direction perpendicular to the second base substrate, and the first light shading layer, the first light transmitting layer, the second light shading layer, and the second light transmitting layer constitute the collimating optical layer.

Optionally, in the method provided by the embodiments of the present disclosure, fabricating the light filter layer, the collimating optical layer, and the plurality of microlenses on the second base substrate includes:

sequentially fabricating the light filter layer and a second light transmitting layer on the second base substrate, a sum of thicknesses of the second base substrate, the light filter layer, and the second light transmitting layer in a direction perpendicular to the second base substrate being smaller than or equal to a focal length of each of the microlenses to be fabricated;

fabricating the plurality of microlenses on the second light transmitting layer, the orthographic projection of each of the microlenses on the second base substrate completely covers orthographic projections of one of the light transmitting holes included in a light shading layer to be fabricated and at least two of the sensors; and

fabricating a second light shading layer, a first light transmitting layer, and a first light shading layer in sequence on one side of the second base substrate facing away from the light filter layer. The first light shading layer and the second light shading layer include the plurality of light transmitting holes which completely coincide in the direction perpendicular to the second base substrate, and the first light shading layer, the first light transmitting layer, the second light shading layer, and the second light transmitting layer constitute the collimating optical layer.

Optionally, in the method provided by the embodiments of the present disclosure, fabricating the light filter layer, the collimating optical layer, and the plurality of microlenses on the second base substrate includes:

fabricating the light filter layer, a first light shading layer, a first light transmitting layer, a second light shading layer, a second light transmitting layer, and the plurality of microlenses in sequence on the second base substrate.

The first light shading layer and the second light shading layer include the plurality of light transmitting holes in a direction perpendicular to the second base substrate, and the first light shading layer, the first light transmitting layer, the second light shading layer, and the second light transmitting layer constitute the collimating optical layer.

The orthographic projection of each of the microlenses on the second base substrate completely covers orthographic projections of one of the light transmitting holes and at least two of the sensors.

Optionally, the method provided by the embodiments of the present disclosure, after fabricating the second light transmitting layer, and before fabricating of the plurality of microlenses, further includes:

fabricating a third light shading layer on the second light transmitting layer. An orthographic projection of the third light shading layer on the second base substrate covers gaps between the microlenses and overlaps with edge areas of the orthographic projections of the plurality of microlenses.

### BRIEF DESCRIPTION OF THE DRAWINGS

FIG. 1 is a schematic diagram of a planar structure of a fingerprint recognition module provided by an embodiment of the present disclosure.

FIG. 2 is a schematic diagram of a cross-sectional structure along a line I-II in FIG. 1.

FIG. 3 is a schematic diagram of an amplified structure of an area A in FIG. 2.

FIG. 4 is a schematic diagram of another planar structure of a fingerprint recognition module provided by an embodiment of the present disclosure.

FIG. 5 is a schematic diagram of a cross-sectional structure along a line III-IV in FIG. 4.

FIG. 6 is a schematic diagram of yet another cross-sectional structure along a line I-II in FIG. 1.

FIG. 7 is a schematic diagram of yet another cross-sectional structure along a line III-IV in FIG. 4.

FIG. 8 is a schematic diagram of yet another cross-sectional structure along a line I-II in FIG. 1.

FIG. 9 is a schematic diagram of yet another cross-sectional structure along a line III-IV in FIG. 4.

FIG. 10 is a schematic diagram of yet another cross-sectional structure along a line I-II in FIG. 1.

FIG. 11 is a schematic diagram of yet another cross-sectional structure along a line III-IV in FIG. 4.

FIG. 12 is a schematic diagram of yet another cross-sectional structure along a line I-II in FIG. 1.

FIG. 13 is a schematic diagram of yet another cross-sectional structure along a line III-IV in FIG. 4.

FIG. 14 is a schematic diagram of yet another cross-sectional structure along a line I-II in FIG. 1.

FIG. 15 is a schematic diagram of yet another cross-sectional structure along a line III-IV in FIG. 4.

FIG. 16 is a fingerprint image of a fingerprint recognition module in the related art.

FIG. 17 is a fingerprint image of a fingerprint recognition module provided by an embodiment of the present disclosure.

FIG. 18 is a flowchart of a method for fabricating the fingerprint recognition module of FIG. 2.

FIG. 19 is a flowchart of a method for fabricating the fingerprint recognition module of FIG. 5.

FIG. 20 is a flowchart of a method for fabricating the fingerprint recognition module of FIG. 6.

FIG. 21 is a flowchart of a method for fabricating the fingerprint recognition module of FIG. 7.

FIG. 22 is a flowchart of a method for fabricating the fingerprint recognition module of FIG. 8.

FIG. 23 is a flowchart of a method for fabricating the fingerprint recognition module of FIG. 9.

FIG. 24 is a flowchart of a method for fabricating the fingerprint recognition module of FIG. 10.

FIG. 25 is a flowchart of a method for fabricating the fingerprint recognition module of FIG. 11.

FIG. 26 is a flowchart of a method for fabricating the fingerprint recognition module of FIG. 12.

FIG. 27 is a flowchart of a method for fabricating the fingerprint recognition module of FIG. 13.

FIG. 28 is a flowchart of a method for fabricating the fingerprint recognition module of FIG. 14.

FIG. 29 is a flowchart of a method for fabricating the fingerprint recognition module of FIG. 15.

FIG. 30 is a schematic structural diagram of a display device provided by an embodiment of the present disclosure.

### DETAILED DESCRIPTION OF THE EMBODIMENTS

In order to make the objectives, technical solutions and advantages of embodiments of the present disclosure clearer, the technical solutions of the embodiments of the present disclosure will be clearly and completely described below in conjunction with the accompanying drawings of the embodiments of the present disclosure. It is noted that the sizes and shapes of various figures in the drawings do not reflect the true scale, but intend to merely illustrate the contents of the present disclosure. The same or similar reference numbers throughout refer to the same or similar elements or elements having the same or similar function. Clearly, the described embodiments are some, but not all, embodiments of the present disclosure. Based on the described embodiments of the present disclosure, all other embodiments obtained by a person of ordinary skill in the art without inventive work fall within the protection scope of the present disclosure.

Unless otherwise defined, technical or scientific terms used herein should be commonly understood by a person of ordinary skill in the art to which the present disclosure belongs. The terms “first”, “second” and the like, as used in the description and in the claims, do not denote any order, quantity, or importance, but are merely used to distinguish one component from another. The word “including” or “containing” and the like means that elements or items preceding the word appear to include elements or items and equivalents thereof listed after the word without excluding other elements or items. “Inner”, “outer”, “upper”, “lower” and the like are only used to indicate relative position relationships, which may change accordingly when the absolute position of a described object changes.

In a current solution that fingerprint recognition is achieved by using microlenses to focus reflected light rays of a fingerprint to a sensor (photosensor), one microlens corresponds to one sensor, and during fingerprint recognition, light reflected by valleys or ridges is converged through the microlens and then irradiates on the corresponding sensor. However, in the current solution, reflected light signals received by the sensors are weak, and consequently the accuracy of fingerprint recognition is affected.

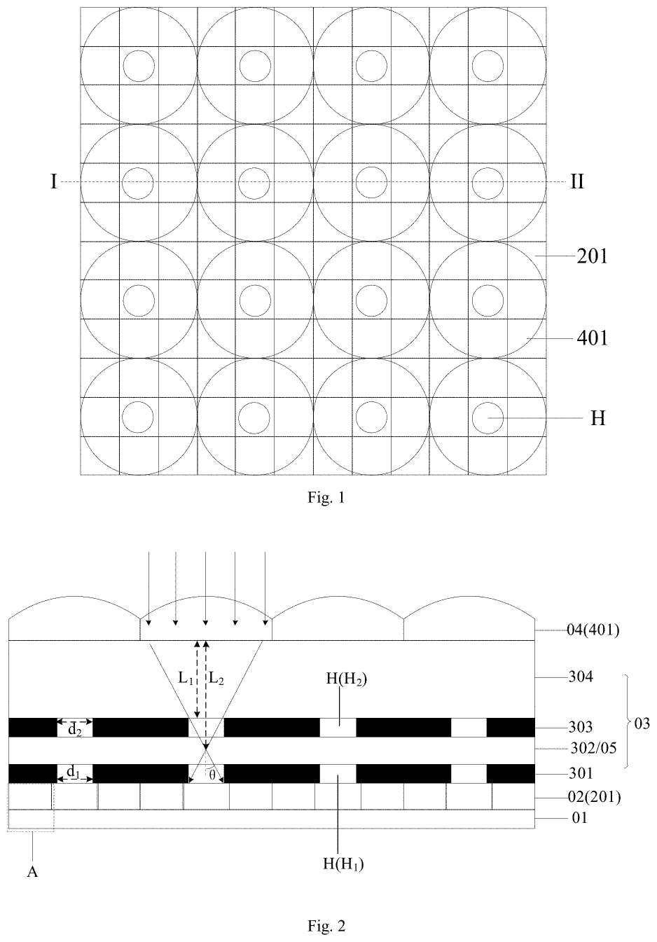

In response to the above-mentioned problems existing in the related art, embodiments of the present disclosure provide a fingerprint recognition module, as shown in FIGS. 1 and 2, including:

a first base substrate 01;

an image sensing layer 02 including a plurality of sensors 201 on the first base substrate 01;

a collimating optical layer 03 located on incident sides of the plurality of sensors 201 and including a plurality of light transmitting holes H; and

a light guiding layer 04 located on a side, facing away from the plurality of sensors 201, of the collimating optical layer 03 and including a plurality of microlenses 401.

The plurality of light transmitting holes H are formed in one-to-one correspondence with part of the sensors 201, and an orthographic projection, on the first base substrate 01, of each of the light transmitting holes H lies in an orthographic projections, on the first base substrate 01, of the corresponding sensor 201.

An orthographic projection, on the first base substrate 01, of each of the microlenses 401 completely covers orthographic projections, on the first base substrate 01, of one of the light transmitting holes H and at least two of the sensors 201, and each of the microlenses 401 is configured to converge light rays reflected by a finger and then transmit the converged light rays to the one sensor 201 that it covers through the one light transmitting hole H that it covers.

In the fingerprint recognition module provided by the embodiments of the present disclosure, a microlens 401 is arranged to correspondingly cover multiple sensors 201, the microlens 401 may converge reflected light that should have been transmitted to the multiple sensors 201 to one of the multiple sensors 201, thereby effectively increasing the intensity of the reflected light received by the sensor 201 and improving the accuracy of fingerprint recognition.

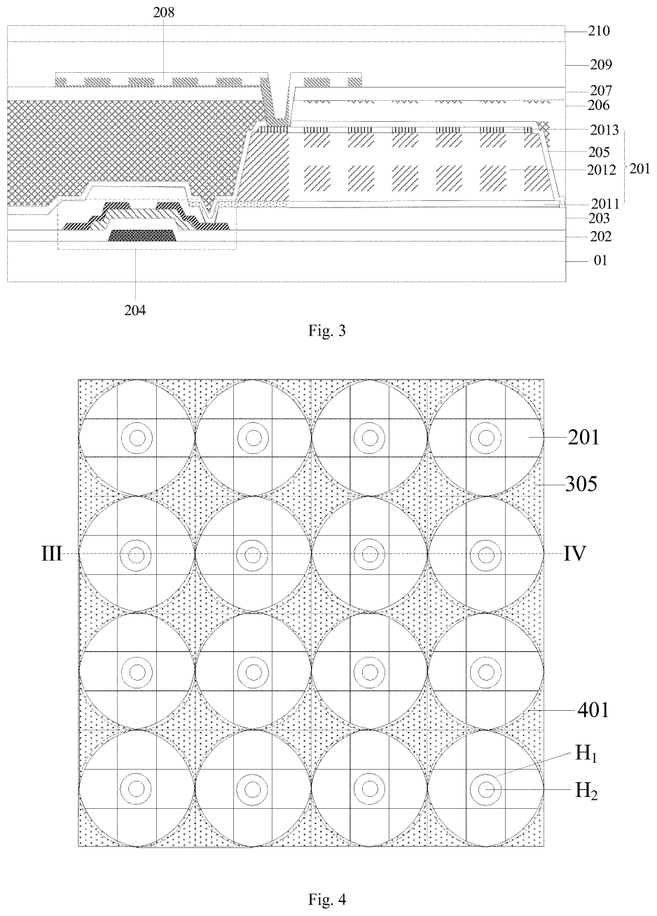

Each of the microlenses 401 may be made of a material with good light transmitting property and stable properties, e.g., polycarbonate (PC), a liquid crystal polymer (LCP), etc. In addition, as shown in FIG. 3, each of the sensors 201 may include a metal electrode 2011, a photoelectric conversion layer 2012, and a light transmitting electrode 2013 disposed in a stacked manner. The metal electrode 2011 is electrically connected with a drain or a source of a first transistor 204 through a via hole penetrating through a first insulating layer 203. The light transmitting electrode 2013 is electrically connected with a bias voltage line 208 through a via hole penetrating through a first flat layer 206 and a second insulating layer 207. The photoelectric conversion layer 2012 is composed of a P-type semiconductor layer, an intrinsic semiconductor layer, and an N-type semiconductor layer disposed in a stacked manner. Generally, a first gate insulating layer 202 located between a gate of the first transistor 204 and an active layer, and a third insulating layer 209 and a scintillator layer 210 disposed in sequence on one side of the bias voltage line 208 facing away from the first base substrate may also be included in the present disclosure. Optionally, the first transistor 204 may be a semiconductor (a-Si) transistor, a low-temperature polysilicon (LTPS) transistor, or an oxide transistor. The first base substrate 01 may be a silicon-based substrate or a glass-based substrate, which is not limited here.

Optionally, in the fingerprint recognition module provided by the embodiments of the present disclosure, as shown in FIGS. 1 and 4, a center of the orthographic projection of the microlens 401 on the first base substrate 01 coincide with a center of the orthographic projection of the light transmitting hole H which is completely covered by the microlens 401.

The light transmitting holes H in the collimating optical layer 03 have a collimating effect on the fingerprint reflected light, and the light transmitting holes H are not too large in order to guarantee a better collimating effect. By making the center of the orthographic projection of the microlens 401 on the first base substrate 01 coincide with the center of the orthographic projection of the light transmitting hole H which is completely covered by the microlens 401, the converged light rays of the microlens 401 may also fully transmit to the sensor 201 through the light transmitting hole H with a small size, thereby effectively guaranteeing a collimating effect on the fingerprint reflected light on the basis of increasing the intensity of the fingerprint reflected light received by the sensor 201.

It needs to be noted that FIG. 1 only exemplarily shows a round shape of each of the light transmitting holes H, and a shape of each of the light transmitting holes H may also be square, etc. during specific implementation, which is not limited here. In addition, FIG. 1 specifically shows that the microlenses 401 are closely arranged, and one of the microlenses 401 covers 3*3 sensors 201. Certainly, during specific implementation, the number of sensors 201 which may be covered by one of the microlenses 401 may be designed according to actual demands, which is not limited here. However, in order to effectively ensure that the converged light rays of the microlens 401 may be transmitted through the light transmitting hole H to one of the sensors 201, preferably, the microlens 401 covers X*X (X being an odd number larger than 1) sensors 201. In this case, the converged light rays of the microlens 401 are preferably transmitted to the sensor 201 in the ((X+1)/2)^{th} row and in the ((X+1)/2)^{th} column, and an aperture D of the microlens 401 and a length/width size P of the sensor 201 satisfy the following relationship: D=X*P.

Optionally, in the fingerprint recognition module provided by the embodiments of the present disclosure, as shown in FIG. 2, the collimating optical layer 03 includes: a first light shading layer 301, a first light transmitting layer 302, a second light shading layer 303, and a second light transmitting layer 304 disposed in a stacked manner. The first light shading layer 301 is adjacent to the plurality of sensors 201, and the second light transmitting layer 304 is adjacent to the plurality of microlenses 401.

In a direction perpendicular to the first base substrate 01, a distance L₁ between the second light shading layer 303 and a layer where the plurality of microlenses 401 are located is smaller than or equal to a focal length L₂ of the microlens 401. A ratio of a thickness of the second light transmitting layer 304 to a thickness of the first light transmitting layer 302 may be greater than or equal to 1 and smaller than or equal to 10, specifically e.g., 1, 2, 3, 4, 5, 6, 7, 8, 9, 10, etc. and preferably greater than or equal to 3 and smaller than or equal to 5.

Since the fingerprint reflected light spreads after being converged to focal points by the microlenses 401, in order to make first light transmitting holes H₁ of the first light shading layer 301 and second light transmitting holes H₂ of the second light shading layer 303 smaller, the distance L₁ between the second light shading layer 303 and the layer where the plurality of microlenses 401 are located is smaller than or equal to the focal length L₂ of each of the microlenses 401, and the ratio of the thickness of the second light transmitting layer 304 to the thickness of the first light transmitting layer 302 is larger than or equal to 1 and smaller than or equal to 10. In addition, the first light transmitting layer 302 and the second light transmitting layer 304 may be made of a transparent resin such as polyimide (PI) to avoid loss of the fingerprint reflected light on a transmission path as much as possible.

Optionally, in the fingerprint recognition module provided by the embodiments of the present disclosure, as shown in FIG. 2, orthographic projections of the first light transmitting holes H₁ on the first base substrate 01 completely coincide with orthographic projections of the second light transmitting holes H₂ on the first base substrate 01, i.e., the first light transmitting holes H₁ and the second light transmitting holes H₂ are the same in size.

Stray light transmitted through the gaps between the adjacent microlenses 401 may irradiate through the second light transmitting holes H₂ to the adjacent first light transmitting holes H1 and affects the fingerprint recognition effect. By making the first light transmitting holes H₁ and the second light transmitting holes H₂ the same in size, the stray light may be effectively blocked by using the first light shading layer 301 between the first light transmitting holes H₁, thereby improving fingerprint imaging quality. In specific implementation, as shown in FIG. 2, a diameter d₁ of each of the first light transmitting holes H₁ and a diameter d₂ of each of the second light transmitting holes H₂ may be determined by the distance L₁ between the second light shading layer 303 and the layer where the plurality of microlenses 401 are located, the focal length L₂ of each of the microlenses 401, and a light collection angle θ to be achieved, specifically, d₁=d₂=2*(L₂−L₁)*tan θ.

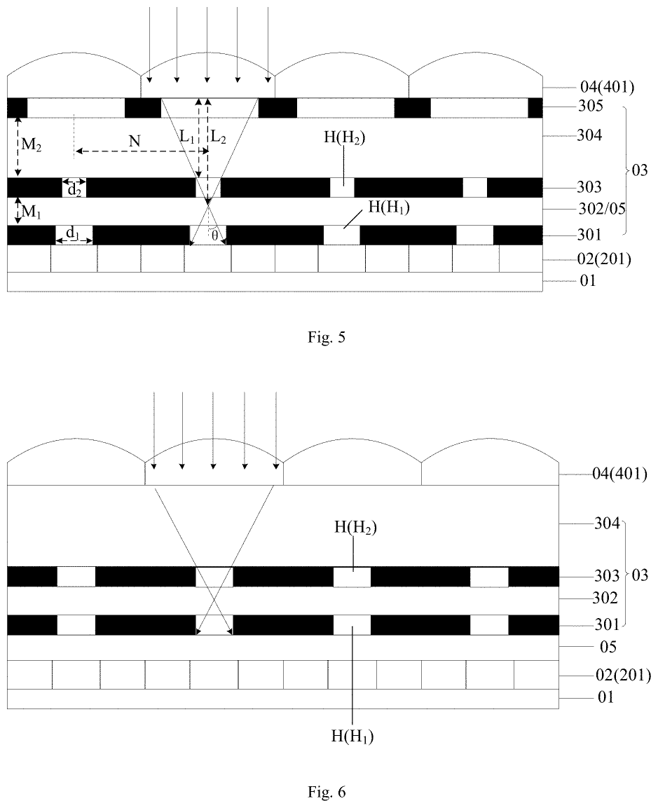

Optionally, in the fingerprint recognition module provided by the embodiments of the present disclosure, as shown in FIGS. 4 and 5, the collimating optical layer 03 may further include: a third light shading layer 305 between the second light transmitting layer 304 and the layer where the plurality of microlenses 401 are located.

An orthographic projection of the third light shading layer 305 on the first base substrate 01 covers the gaps between the microlenses 401 and overlaps with edge areas of the orthographic projections of the plurality of microlenses 401 on the first base substrate 01. Exemplarily, the edge area may account for 0.5%-20% of the area of each of the microlenses 401.

As can be seen in FIG. 4, although the microlenses 401 are closely arranged, the round shapes of the microlenses 401 result in the gaps between the adjacent microlenses 401, and the stray light transmitted through the gaps may irradiate to the sensors 201 and affect fingerprint recognition during fingerprint recognition. By arranging the third light shading layer 305 that completely covers the gaps, the stray light may be effectively blocked, thereby improving the accuracy of fingerprint recognition.

Optionally, in the fingerprint recognition module provided by the embodiments of the present disclosure, thicknesses of the first light shading layer 301, the second light shading layer 303, and the third light shading layer 305 may be greater than 0μm and smaller than or equal to 3 μm, preferably 1 μm, or 0.5 μm, 1.5 μm, 2 μm, 3 μm, etc. Optionally, in the fingerprint recognition module provided by the embodiments of the present disclosure, the first light shading layer 301, the second light shading layer 303, and the third light shading layer 305 may be made of a black matrix (BM) material, molybdenum oxide, aluminum oxide, or chromium metal which are light-absorbing or low-reflectivity materials so as to reduce a degree to which stray light at large angles is reflected on the light shading layers and improve the accuracy of fingerprint recognition.

Optionally, in the fingerprint recognition module provided by the embodiments of the present disclosure, as shown in FIG. 5, the light transmitting holes H include the first light transmitting holes H₁ located in the first light shading layer 301, and the second light transmitting holes H₂ located in the second light shading layer 303.

The orthographic projections of the second light transmitting holes H₂ on the first base substrate 01 lie in the orthographic projections of the first light transmitting holes H₁ on the first base substrate 01.

Since the third light shading layer 305 in FIG. 5 may effectively block stray light, a size of each of the first light transmitting holes H₁ may be suitably increased (e.g. around 10% larger than a size of each of the second light transmitting holes H₂) to further increase the intensity of the fingerprint reflected light incident on the sensors 201. Optionally, as shown in FIG. 5, the diameter d₂ of each of the second light transmitting holes H₂ may be determined by the distance L₁ between the second light shading layer 303 and the layer where the plurality of microlenses 401 are located, the focal length L₂ of each of the microlenses 401, and the light collection angle θ to be achieved, specifically d₂=2*(L₂−L₁)*tan θ, correspondingly, the diameter d₁ of each of the first light transmitting holes H₁ satisfies a relationship: d₁≈2.2*(L₂−L₁)*tan θ. In addition, in the fingerprint recognition module shown in FIG. 5, if the first light shading layer 301, the second light shading layer 303, and the third light shading layer 305 are used as a plane (i.e., negligible thickness), the thickness M₁ of the first light transmitting layer 302 and the thickness M₂ of the second light transmitting layer 304 satisfy the following relationship: (d₁−d₂)/M₁≤(M₁+M₂)/(N+d₂/2), where N is a distance between centers of the adjacent microlenses 401. In specific implementation, 1≤M₂/M₁<10, preferably 3≤M₂/M₁≤5.

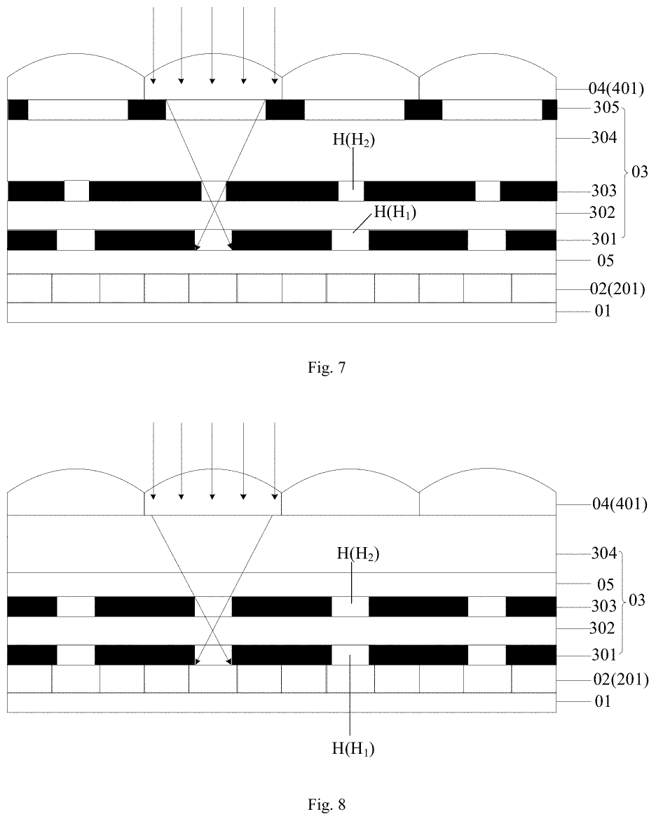

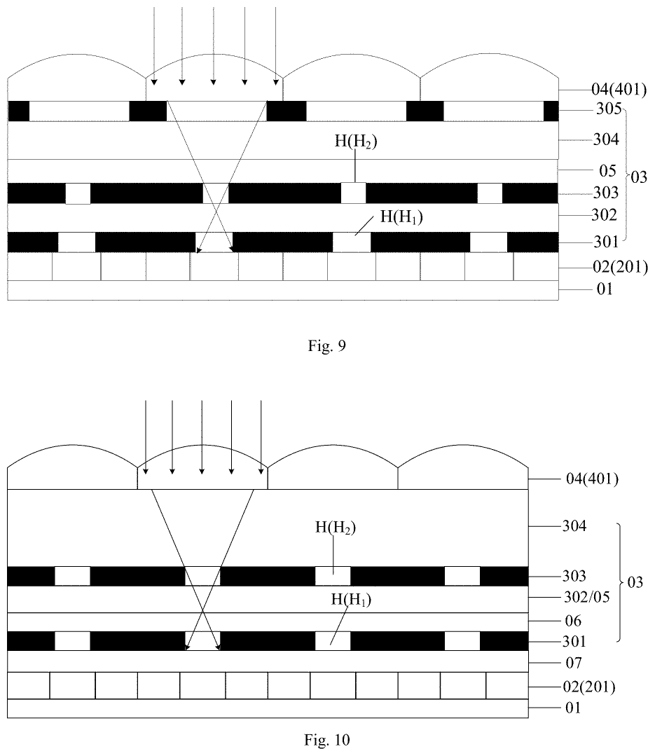

Optionally, in the fingerprint recognition module provided by the embodiments of the present disclosure, at least one of the first light transmitting layer 302 and the second light transmitting layer 304 is multiplexed as a light filter layer 05, and multiplexing of the first light transmitting layer 302 as the light filter layer 05 is specifically illustrated in FIGS. 2 and 5. Since light rays of 600 nm or more in ambient light may irradiate through the finger to the microlenses 401, multiplexing at least one of the first light transmitting layer 302 and the second light transmitting layer 304 as the light filter layer 05 may effectively avoid interference from the ambient light and improve a fingerprint imaging effect. In addition, multiplexing at least one of the first light transmitting layer 302 and the second light transmitting layer 304 as the light filter layer 05 avoids the addition of the light filter layer 05 to the fingerprint recognition module, which facilitates the effect of being light and thin. Of course, in specific implementation, the light filter layer 05 may also be arranged separately. The light filter layer 05 may be arranged between a layer where the plurality of sensors 201 are located and the collimating optical layer 03, as shown in FIGS. 6 and 7, or between the adjacent second light transmitting layer 304 and second light shading layer 303, as shown in FIGS. 8 and 9, or between the collimating optical layer 03 and the layer where the plurality of microlenses 401 are located. Optionally, the light filter layer 05 may be composed of a plurality of high-refractive-index film layers and a plurality of low-refractive-index film layers, and the light filter layer 05 may have a thickness of 1 μm.

Optionally, in the fingerprint recognition module provided by the embodiments of the present disclosure, as shown in FIG. 2 and FIGS. 5 to 9, the image sensing layer 02, the collimating optical layer 03, the light guiding layer 04, and the light filter layer 05 are film layers arranged in a stacked manner on the first base substrate 01; or, as shown in FIGS. 10 to 15, the collimating optical layer 03, the light guiding layer 04, and the light filter layer 05 are film layers arranged in a stacked manner on a second base substrate 06, while the image sensing layer 02 is a film layer on the first base substrate 01, and the plurality of sensors 201 are bound to the stack on the second base substrate 06 by an optical adhesive layer 07.

In addition, the present disclosure also provides a set of comparative data between a fingerprint recognition module in the related art and the fingerprint recognition module provided by the embodiments of the present disclosure. Specifically, a stack relationship of film layers in a structure of the fingerprint recognition module in the related art is the same as a stack relationship of all the film layers shown in FIG. 2, each of the sensors 201 has a length/width size of 3.5 μm and a light collection angle θ of each of the light transmission holes H is of ±4.5°. The differences lie in that: in the related art, one microlens 401 corresponds to one sensor 201, and the microlens 401 has an aperture of 3.5 μm, and a camber of 1 μm, a thickness of the first light transmitting layer 302 is 6 μm, and a thickness of the second light transmitting layer 304 is 3 μm. In FIG. 2, one microlens 401 corresponds to three sensors 201, and the microlens 401 has an aperture of 10 μm, and a camber of 3.5 μm, the thickness of the first light transmitting layer 302 is 10 μm, and the thickness of the second light transmitting layer 304 is 2 μm. The results show that in the related art, the transmittance of the fingerprint reflected light is 22% and the total energy of the reflected light received by a single sensor 201 is 0.023; and in FIG. 2, the transmittance of the fingerprint reflected light is 19%, and the total energy of the reflected light received by the single sensor 201 is 0.191. As such, the fingerprint recognition module provided by the embodiments of the present disclosure increases the intensity of the reflected light received by the sensors 201 when thicknesses of the fingerprint recognition modules are close, thereby improving the accuracy of fingerprint recognition.

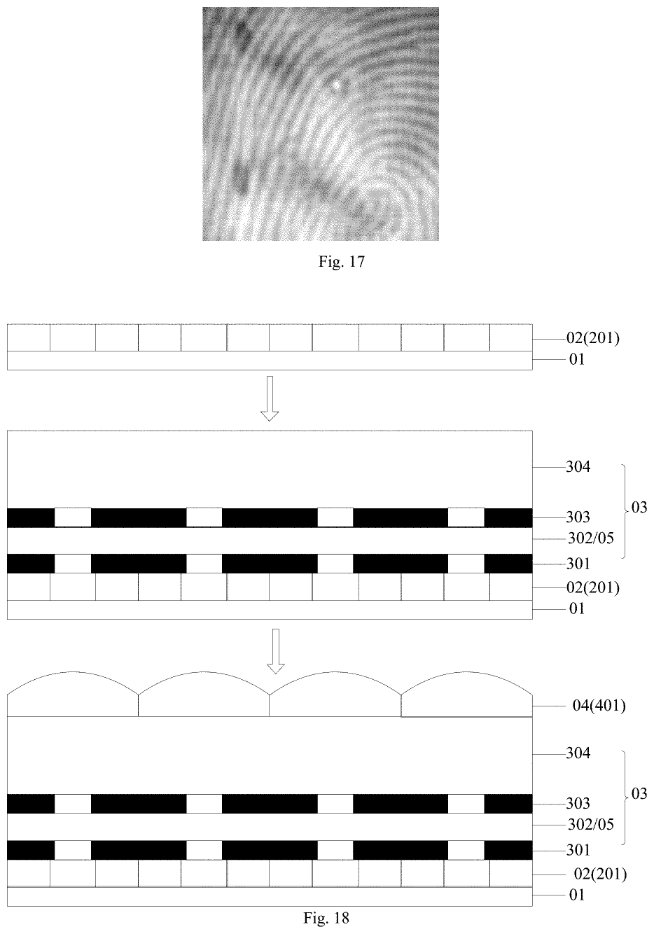

Furthermore, the present disclosure further provides comparative data between the fingerprint recognition module in the foregoing related art and the fingerprint recognition module provided by the present disclosure that multiplexes the first light transmitting layer 302 as the light filter layer 05. Specifically, in the foregoing related art, the fingerprint recognition module has a signal of 28.87 and a Signal-to-Noise Ratio (SNR) of 15.68, and fingerprint imaging is shown in FIG. 16; and the fingerprint recognition module of the present disclosure that multiplexes the first light transmitting layer 302 as the light filter layer 05 has a signal of 38.19 and a Signal-to-Noise Ratio (SNR) of 26.83, and fingerprint imaging is shown in FIG. 17. In contrast, after adding a light filtering function of the light filter layer 05 in the present disclosure, the signal and the Signal-to-Noise Ratio are significantly improved and a fingerprint image is clearer.

Accordingly, embodiments of the present disclosure further provide a method for fabricating a fingerprint recognition module, and since a problem-solving principle of the method is similar to that of the fingerprint recognition module, implementation of the method may be referred to the embodiments of the fingerprint recognition module, and repetition is omitted.

Specifically, the method for fabricating the fingerprint recognition module shown in FIG. 2 and FIGS. 5 to 9, as shown in FIGS. 18 to 23, may include the following steps:

a base substrate is provided; and

an image sensing layer including a plurality of sensors, a collimating optical layer, and a light guiding layer including a plurality of microlenses are fabricated in sequence on the base substrate.

The collimating optical layer includes a plurality of light transmitting holes formed in one-to-one correspondence with part of the sensors, and orthographic projections of the light transmitting holes on the base substrate lie in orthographic projections of the sensors disposed corresponding thereto.

An orthographic projection of each of the microlenses on the base substrate completely covers orthographic projections of one of the light transmitting holes and at least two of the sensors, and each of the microlenses is configured to converge light rays reflected by a finger and then transmit the converged light rays to the corresponding sensor through the corresponding light transmitting hole.

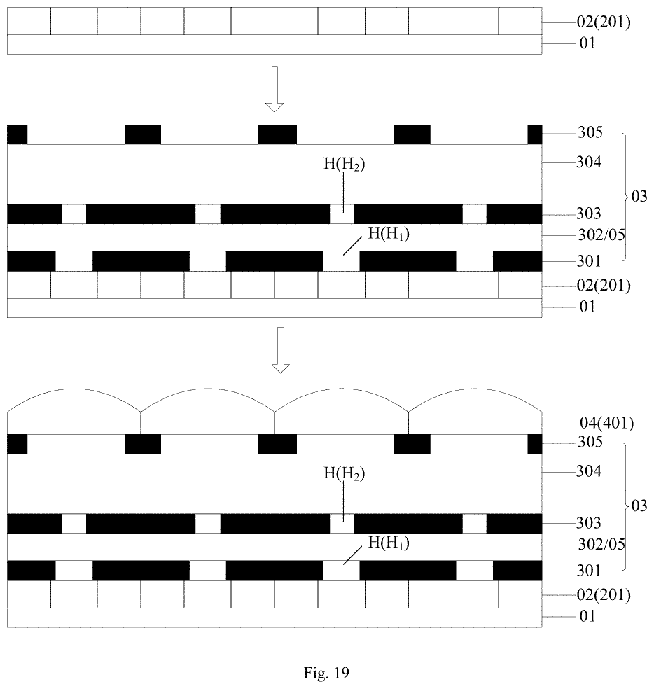

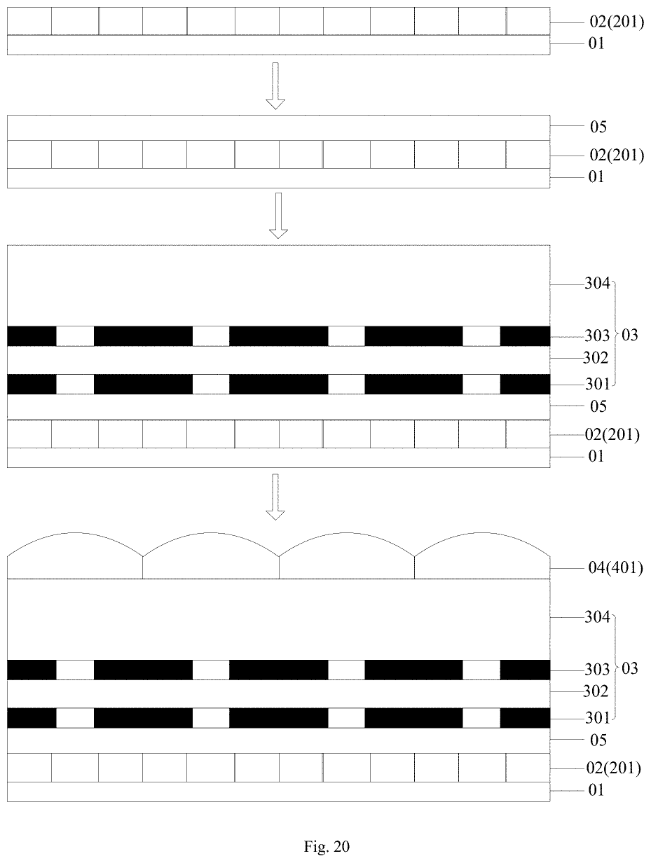

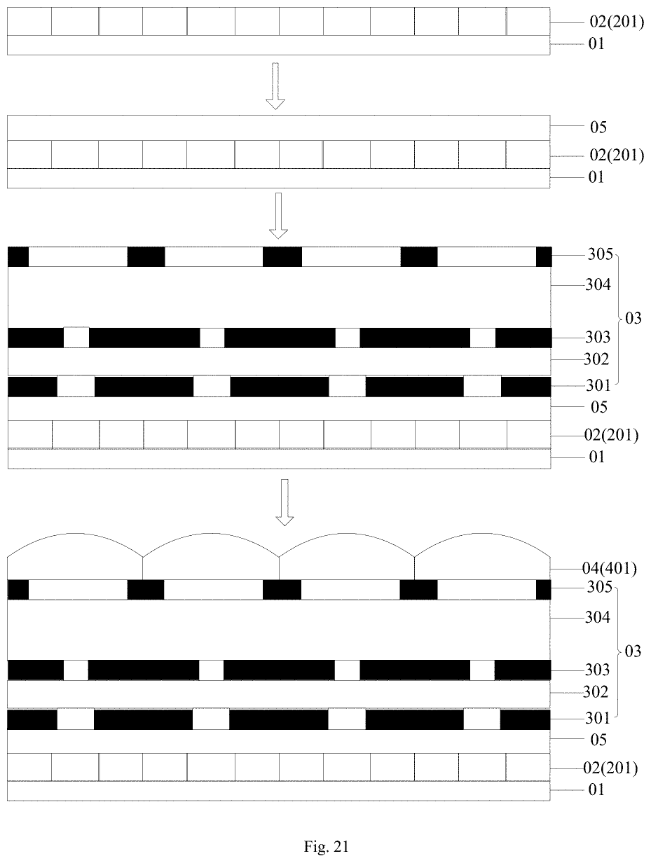

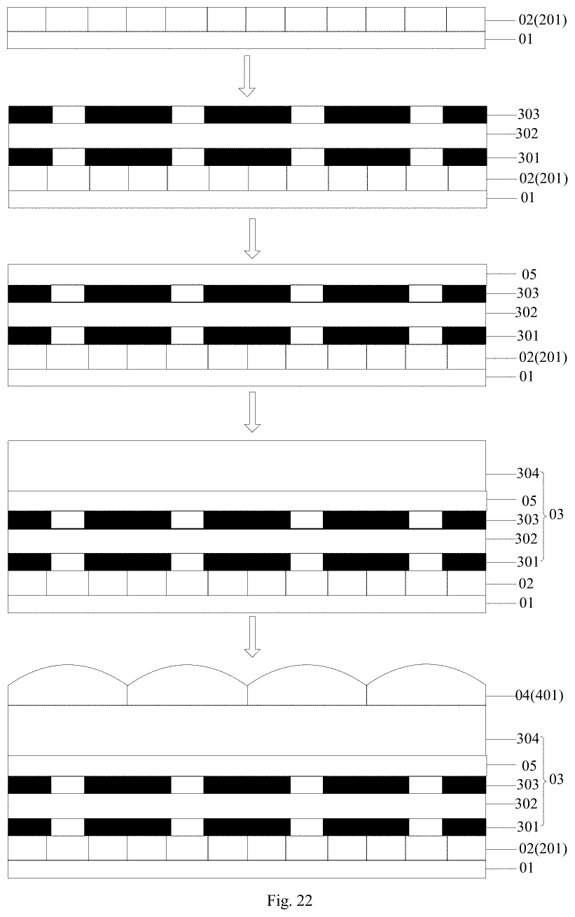

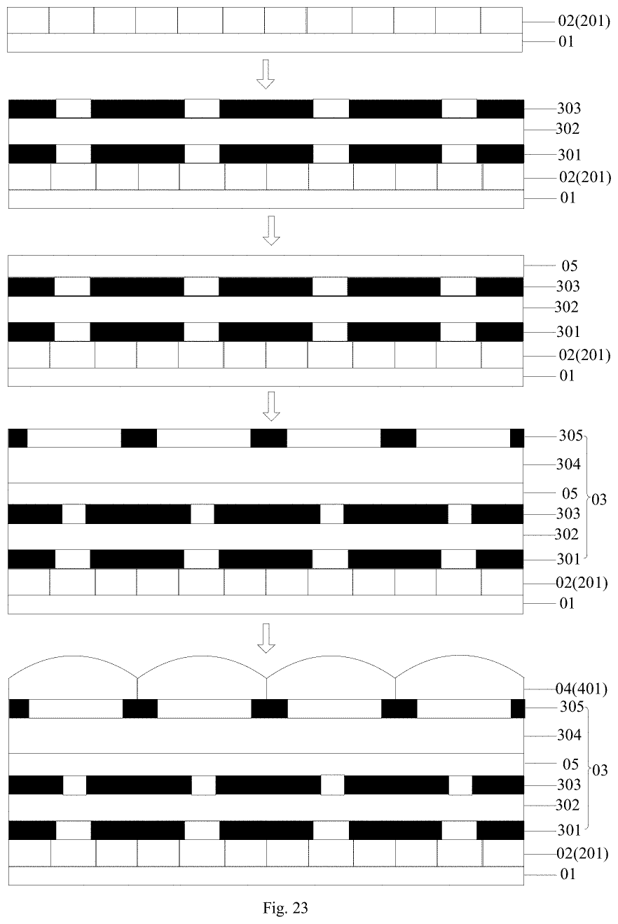

In specific implementation, for the fingerprint recognition module shown in FIGS. 2 and 5, since the first light transmitting layer 302 is multiplexed as a light filter layer 05, it can be fabricated using the specific steps described above, as shown in FIGS. 18 and 19. For the fingerprint recognition module shown in FIGS. 6 and 7, as shown in FIGS. 20 and 21, after the image sensing layer 02 including the plurality of sensors 201 is fabricated on the base substrate, and before the collimating optical layer 03 is fabricated, the light filter layer 05 is also required to be fabricated on the image sensing layer 02 including the plurality of sensors 201. For the fingerprint recognition module shown in FIGS. 8 and 9, as shown in FIGS. 22 and 23, after the second light shading layer 303 is fabricated, and before the second light transmitting layer 304 is fabricated, the light filter layer 05 is also fabricated on the second light shading layer 303.

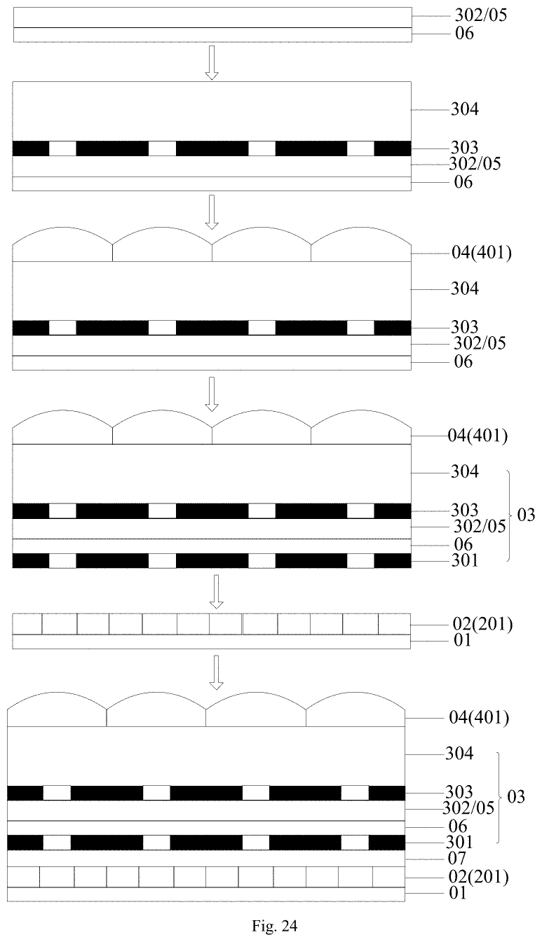

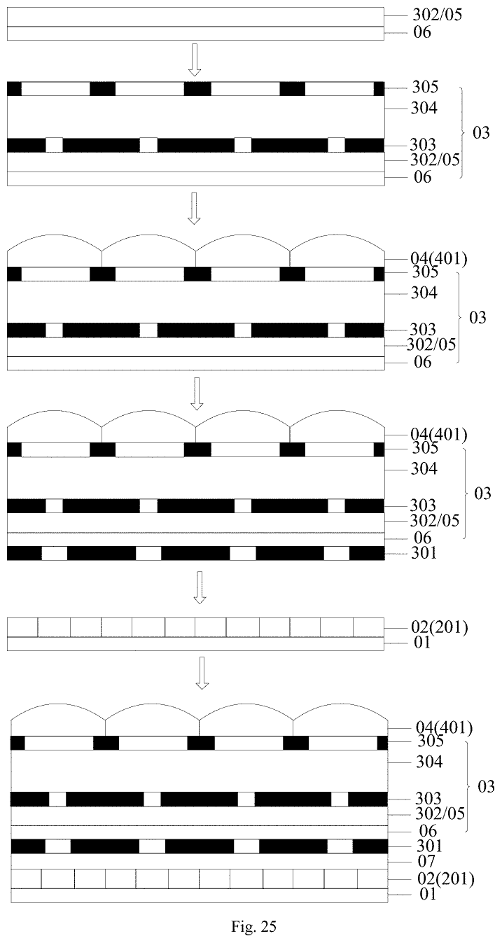

Specifically, the method for fabricating the fingerprint recognition module shown in FIGS. 10 to 15, as shown in FIGS. 24 to 29, may include the following steps:

a first base substrate is provided;

an image sensing layer including a plurality of sensors is fabricated on the first base substrate;

a second base substrate is provided;

a light filter layer, a collimating optical layer, and a light guiding layer including a plurality of microlenses are fabricated on the second base substrate, herein the collimating optical layer includes a plurality of light transmitting holes, an orthographic projection of each of the microlenses on the second base substrate completely covers one light transmitting hole; and

the second base substrate with the light filter layer, the collimating optical layer, and the plurality of microlenses is attached to incident sides of the plurality of sensors by using an optical adhesive, such that the plurality of light transmitting holes are formed in one-to-one correspondence with part of the sensors after attachment.

An orthographic projection of the light transmitting hole on the second base substrate is located in an orthographic projections of the sensor corresponding to the light transmitting hole on the second base substrate,. An orthographic projection of each of the microlenses on the second base substrate completely covers the orthographic projections of at least two of the sensors. Each of the microlenses is configured to converge light rays reflected by a finger and then transmit the converged light rays to one of the sensors that the each microlens covers through the light transmitting hole that the each microlens covers.

In specific implementation, for the fingerprint recognition module shown in FIG. 10, fabricating the light filter layer, the collimating optical layer, and the plurality of microlenses on the second base substrate may be implemented through the following mode.

As shown in FIG. 24, a first light transmitting layer 302, a second light shading layer 303, and a second light transmitting layer 304 are fabricated in sequence on the second base substrate 06. The first light transmitting layer 302 is multiplexed as the light filter layer 05. A thickness, in a direction perpendicular to the second base substrate 06, of the second light transmitting layer 304 is smaller than or equal to a focal length of each of the microlenses 401 to be fabricated, and the second light shading layer 303 includes a plurality of second light transmitting holes.

The plurality of microlenses 401 are fabricated on the second light transmitting layer 304. The orthographic projection of each of the microlenses 401 on the second base substrate 06 completely covers orthographic projections of one of the second light transmitting holes and at least two of the sensors 201 on the second base substrate 06.

A first light shading layer 301 is fabricated on one side of the second base substrate 06 facing away from the first light transmitting layer 302. The first light shading layer 301 includes a plurality of first light transmitting holes which completely coincide with the plurality of second light transmitting holes in a direction perpendicular to the second base substrate 06. The first light shading layer 301, the first light transmitting layer 302, the second light shading layer 303, and the second light transmitting layer 304 constitute the collimating optical layer 03.

In specific implementation, the method for fabricating the fingerprint recognition module shown in FIG. 11 is similar to the method for fabricating the fingerprint recognition module shown in FIG. 10. The only difference is that, as shown in FIG. 25, after fabricating the second light transmitting layer 304, and before fabricating the plurality of microlenses 401, a third light shading layer 305 also needs to be fabricated. The third light shading layer 305 covers gaps between the microlenses 401 and an edge area of each of the microlenses 401.

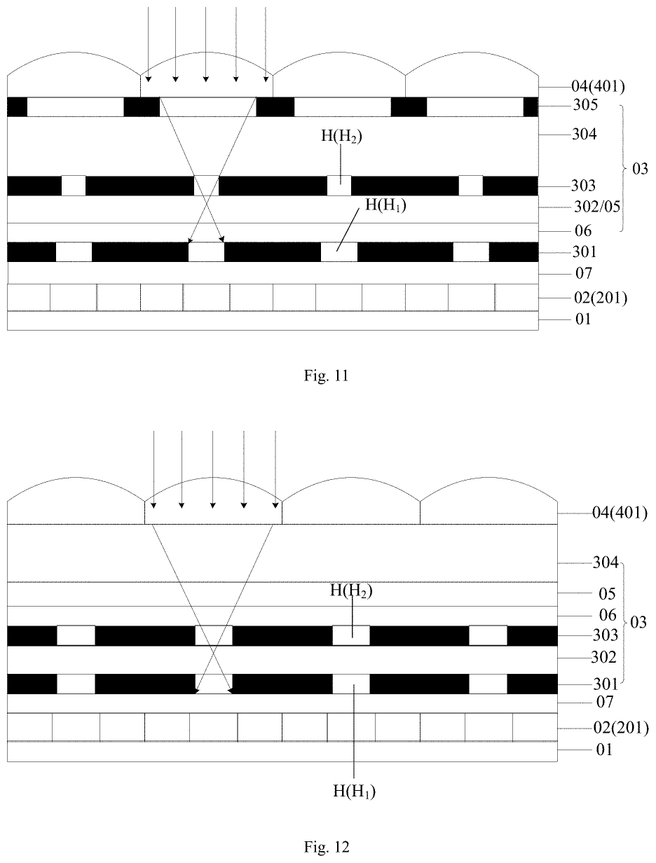

In specific implementation, for the fingerprint recognition module shown in FIG. 12, fabricating the light filter layer, the collimating optical layer, and the plurality of microlenses on the second base substrate may be implemented specifically through the following mode.

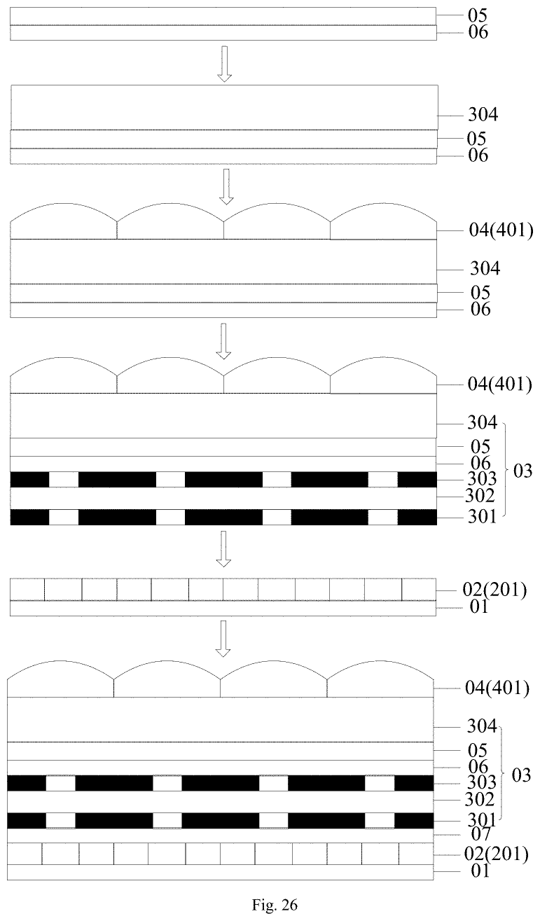

As shown in FIG. 26, the light filter layer 05 and the second light transmitting layer 304 are sequentially fabricated on the second base substrate 06. A sum of thicknesses, in a direction perpendicular to the second base substrate 06, of the second base substrate 06, the light filter layer 05, and the second light transmitting layer 304 is smaller than or equal to a focal length of each of the microlenses 401 to be fabricated.

The plurality of microlenses 401 are fabricated on the second light transmitting layer 304. The orthographic projection of each of the microlenses 401 on the second base substrate 06 completely covers the orthographic projections of one of the light transmitting holes included in the light shading layer to be fabricated and at least two of the sensors 201.

The second light shading layer 303, the first light transmitting layer 302, and the first light shading layer 301 are sequentially fabricated on one side of the second base substrate 06 facing away from the light filter layer 05. The first light shading layer 301 and the second light shading layer 302 include the plurality of light transmitting holes which completely coincide in a direction perpendicular to the second base substrate 06, and the first light shading layer 301, the first light transmitting layer 302, the second light shading layer 303, and the second light transmitting layer 304 constitute the collimating optical layer 03.

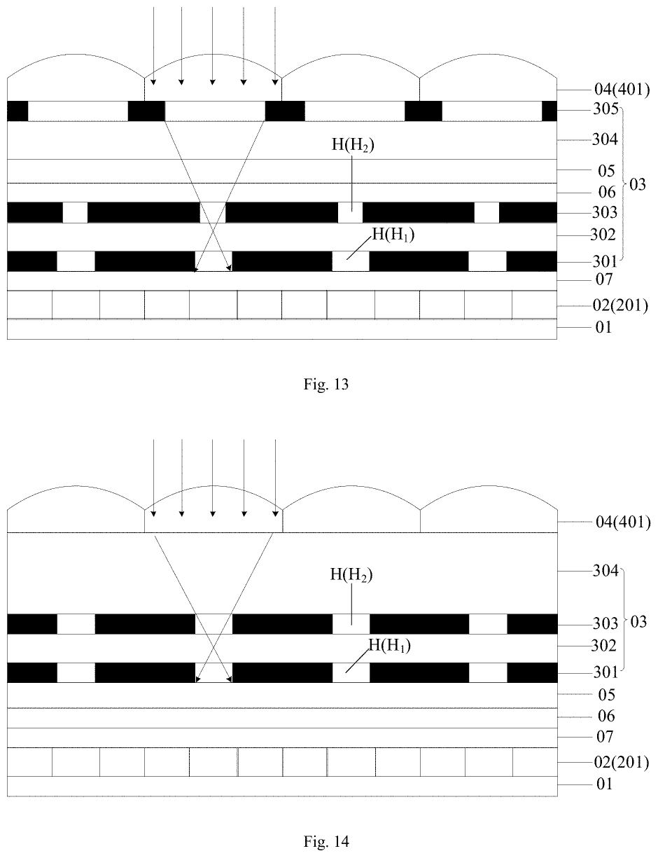

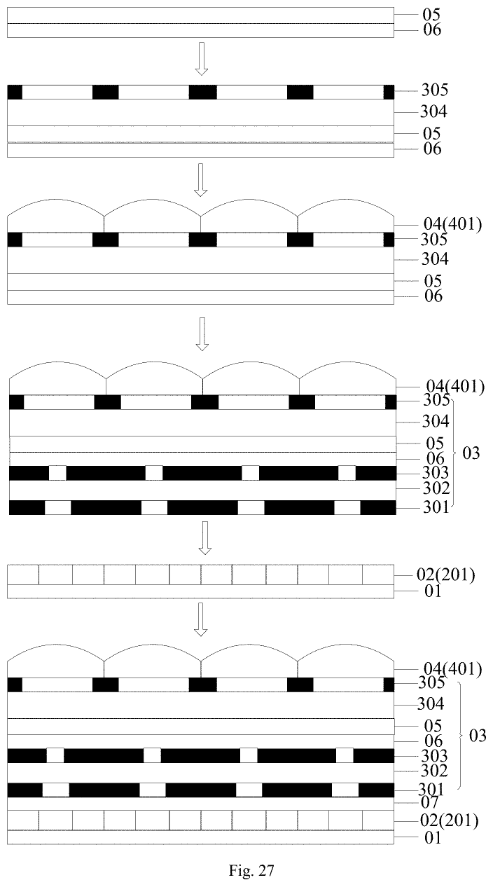

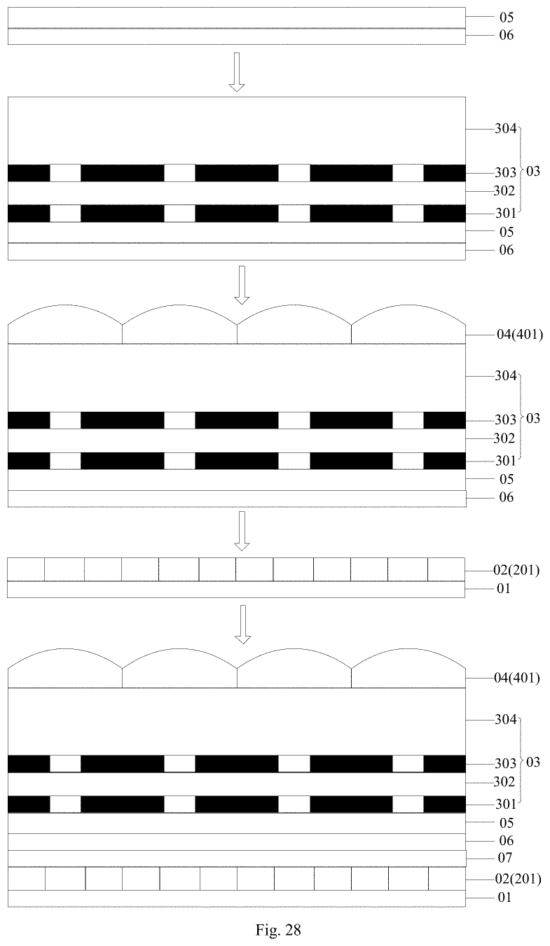

In specific implementation, the method for fabricating the fingerprint recognition module shown in FIG. 13 is similar to the method for fabricating the fingerprint recognition module shown in FIG. 12. The only difference is that, as shown in FIG. 27, after fabricating the second light transmitting layer 304, and before fabricating the plurality of microlenses 401, the third light shading layer 305 also needs to be fabricated. The third light shading layer 305 covers the gaps between the microlenses 401 and the edge area of each of the microlenses 401.

In specific implementation, for the fingerprint recognition module shown in FIG. 14, fabricating the light filter layer, the collimating optical layer, and the plurality of microlenses on the second base substrate may be implemented through the following mode.

As shown in FIG. 28, the light filter layer 05, the first light shading layer 301, the first light transmitting layer 302, the second light shading layer 303, the second light transmitting layer 304, and a plurality of prisms 04 are sequentially fabricated on the second base substrate 06.

The first light shading layer 301 and the second light shading layer 302 include the plurality of light transmitting holes in a direction perpendicular to the second base substrate 06, and the first light shading layer 301, the first light transmitting layer 302, the second light shading layer 303, and the second light transmitting layer 304 constitute the collimating optical layer 03.

The orthographic projection of each of the microlenses 401 on the second base substrate 06 completely covers the orthographic projections of one of the light transmitting holes and at least two of the sensors 201.

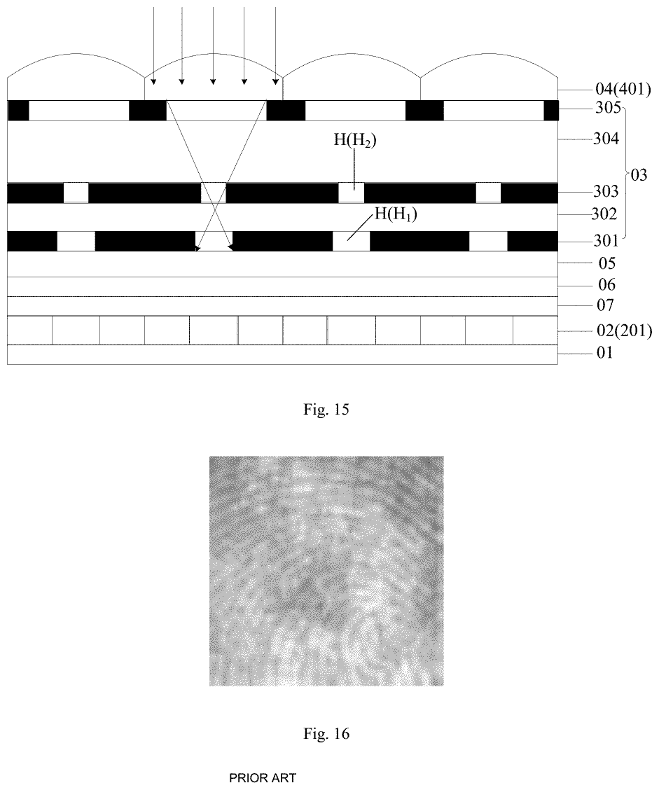

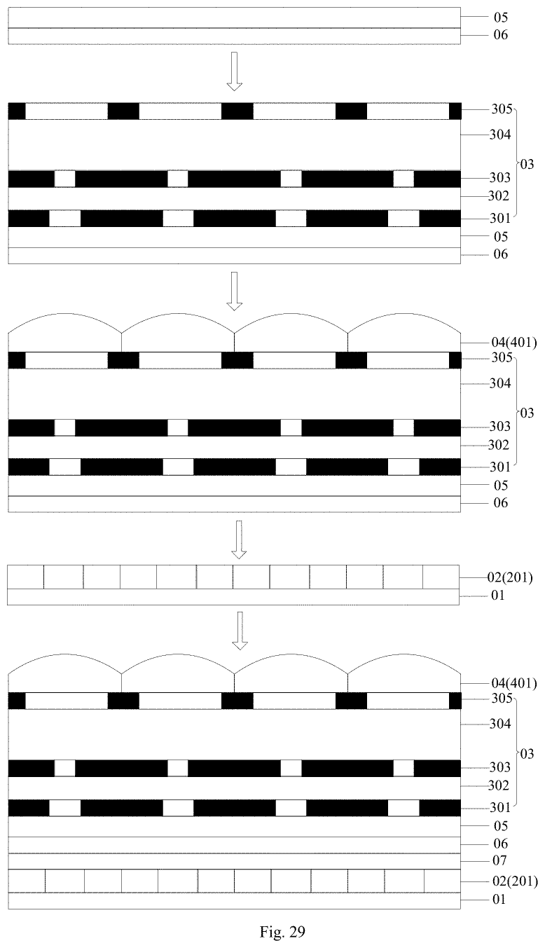

In specific implementation, the method for fabricating the fingerprint recognition module shown in FIG. 15 is similar to the method for fabricating the fingerprint recognition module shown in FIG. 14. The only difference is that, as shown in FIG. 29, after fabricating the second light transmitting layer 304, and before fabricating the plurality of microlenses 401, the third light shading layer 305 also needs to be fabricated. The third light shading layer 305 covers the gaps between the microlenses 401 and the edge area of each of the microlenses 401.

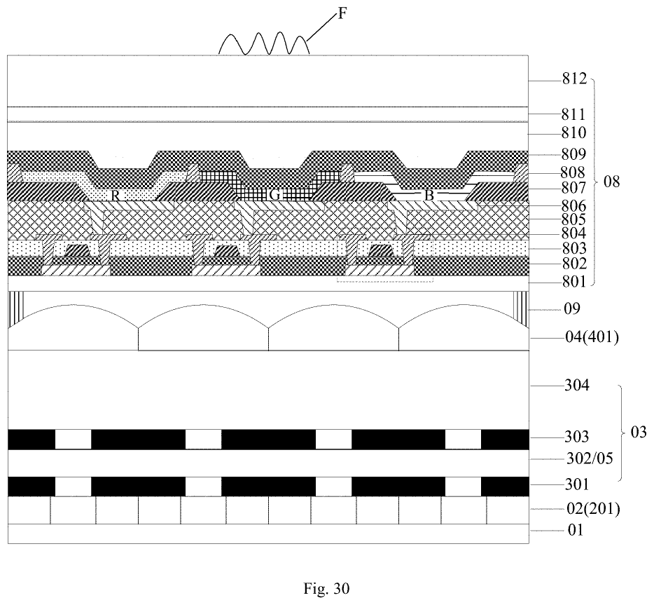

According to the same inventive concept, embodiments of the present disclosure provide a display device, as shown in FIG. 30, including a display module 08, a fingerprint recognition module located on an opposite side of a display surface of the display module 08, and an adhesive layer 09 located between the display module 08 and the fingerprint recognition module. The fingerprint recognition module is the fingerprint recognition module described above, an orthographic projection of the adhesive layer 09 on the display module 08 is located in a frame area (i.e., a peripheral area of a display area AA) of the display module 08 such that an air gap defined by the adhesive layer 09 is formed between a plurality of microlenses 401 and the display module 08. Optionally, the adhesive layer 09 may be an optically clear adhesive (OCA) or an optical clear resin (OCR). The display module 08 may be an organic light-emitting diode (OLED) display module, a quantum dot light-emitting diode (QLED) display module, or a micro light-emitting diode (Micro-LED) display module.

Specifically, when the display module 08 may be the organic light-emitting diode (OLED) display module, as shown in FIG. 30, the display module 08 may specifically include: a third base substrate 801, a second gate insulating layer 802, an interlayer insulating layer 803, a second transistor 804, anodes 806, a pixel defining layer 807, a light-emitting functional layer R/G/B, a support layer 808, a cathode 809, an encapsulation layer 810, an adhesive layer 811, and a protective cover sheet 812. In the fingerprint recognition process, reflected light of a fingerprint F is transmitted through an area between the anodes 806 to the microlenses 401, and is converged by the microlenses 401 and then transmitted through a collimating optical layer 03 to one of sensors 201. Since one of the microlenses 401 correspondingly covers multiple sensors 201 such that the microlens 401 may converge the reflected light which should have been transmitted to the multiple sensors 201 to one of the sensors 201, the intensity of the reflected light received by the one sensor 201 is effectively increased, and the accuracy of fingerprint recognition is improved.

Optionally, the display device may be: any display-enabled product or component like a mobile phone, a tablet PC, a television, a display, a laptop, a digital photo frame, a navigator, a smartwatch, a fitness band, a personal digital assistant, etc. Other essential components to the display device will be understood by those of ordinary skill in the art and will not be described in detail herein, which should not be taken as a limitation on the present disclosure. In addition, since a principle of solving problems of the display device is similar to that of solving problems of the above-described fingerprint recognition module, implementation of the display device may be referred to in the embodiments of the fingerprint recognition module, and repetition is omitted.

It will be apparent to those skilled in the art that various modifications and variations may be made to the embodiments of the present disclosure without departing from the spirit and scope of the embodiments of the present disclosure. In this case, the present disclosure intends to include these modifications and variations if such modifications and variations of the embodiments of the present disclosure fall within the scope of claims and their equivalents.

1. A fingerprint recognition module, comprising:
a base substrate;
an image sensing layer comprising a plurality of sensors located on the base substrate;
a collimating optical layer located on incident sides of the plurality of sensors and comprising a plurality of light transmitting holes; the plurality of light transmitting holes being formed in one-to-one correspondence with part of the plurality of sensors, an orthographic projection, on the base substrate, of each of the light transmitting holes being in an orthographic projection, on the base substrate, of a sensor corresponding to the each light transmitting hole; and
a light guiding layer located on a side, facing away from the plurality of sensors, of the collimating optical layer and comprising a plurality of microlenses; an orthographic projection, on the base substrate, of each of the microlenses completely covering orthographic projections, on the base substrate, of a respective one of the light transmitting holes and at least two of the sensors, and the each microlens is configured to converge light rays reflected by a finger and then transmit the converged light rays to one of the at least two sensors that the each microlens covers through the respective one light transmitting hole that the each microlens covers.

2. The fingerprint recognition module according to claim 1, wherein a center of the orthographic projection, on the base substrate, of the each microlens coincide with a center of an orthographic projection, on the base substrate, of the respective one light transmitting hole completely covered by the each microlens.

3. The fingerprint recognition module according to claim 1, wherein the collimating optical layer comprises:
a first light shading layer, a first light transmitting layer, a second light shading layer, and a second light transmitting layer disposed in a stacked manner;
wherein the first light shading layer is adjacent to the plurality of sensors, and the second light transmitting layer is adjacent to the plurality of microlenses; and
a distance, in a direction perpendicular to the base substrate, between the second light shading layer and a layer where the plurality of microlenses are located is smaller than or equal to a focal length of each of the microlenses, and a ratio of a thickness of the second light transmitting layer to a thickness of the first light transmitting layer is greater than or equal to 1 and smaller than or equal to 10.

4. The fingerprint recognition module according to claim 3, wherein the light transmitting holes comprise:
first light transmitting holes in the first light shading layer; and
second light transmitting holes in the second light shading layer;
wherein orthographic projections, on the base substrate, of the first light transmitting holes coincide completely with orthographic projections, on the base substrate, of the second light transmitting holes.

5. The fingerprint recognition module according to claim 3, wherein the collimating optical layer further comprises:
a third light shading layer located between the second light transmitting layer and the layer where the plurality of microlenses are located;
wherein an orthographic projection, on the base substrate, of the third light shading layer covers gaps between the microlenses and overlaps with edge areas of orthographic projections, on the base substrate, of the plurality of microlenses.

6. The fingerprint recognition module according to claim 5, wherein the light transmitting holes comprise:
first light transmitting holes in the first light shading layer; and
second light transmitting holes in the second light shading layer;
wherein orthographic projections, on the base substrate, of the second light transmitting holes lie in orthographic projections, on the base substrate, of the first light transmitting holes.

7. The fingerprint recognition module according to claim 5, wherein a thickness, in the direction perpendicular to the base substrate, of each of the first light shading layer, the second light shading layer, and the third light shading layer is greater than 0 μm and smaller than or equal to 3 μm.

8. The fingerprint recognition module according to claim 5, wherein materials of the first light shading layer, the second light shading layer, and the third light shading layer are a black matrix material, molybdenum oxide, aluminum oxide, or chromium metal.

9. The fingerprint recognition module according to claim 3, wherein the first light transmitting layer and/or the second light transmitting layer are/is multiplexed as a light filter layer.

10. The fingerprint recognition module according to claim 3, further comprising:
a light filter layer located:
between the layer where the plurality of microlenses are located and the collimating optical layer, or
between the collimating optical layer and a layer where the plurality of sensors are located, or between the first light shading layer and the first light transmitting layer; or
between the first light transmitting layer and the second light shading layer; or
between the second light shading layer and the second light transmitting layer.

11. The fingerprint recognition module according to claim 9, wherein the light filter layer is configured to filter out ambient light above 600 mm.

12. The fingerprint recognition module according to claim 9, wherein the image sensing layer, the collimating optical layer, the light guiding layer, and the light filter layer are film layers arranged on the base substrate in a stacked manner.

13. The fingerprint recognition module according to claim 1, further comprising:
an optical adhesive layer in contact with surfaces of sides, facing away from the base substrate, of the plurality of sensors.

14. A display device, comprising:
a display module,
a fingerprint recognition module located on an opposite side of a display surface of the display module, and
an adhesive layer located between the display module and the fingerprint recognition module;
wherein the fingerprint recognition module is the fingerprint recognition module according to claim 1; and
an orthographic projection, on the display module, of the adhesive layer is located in a frame area of the display module.

15. A method for fabricating a fingerprint recognition module, comprising:
providing a base substrate; and
sequentially fabricating, on the base substrate, an image sensing layer comprising a plurality of sensors, a collimating optical layer, and a light guiding layer comprising a plurality of microlenses;
wherein the collimating optical layer comprises a plurality of light transmitting holes formed in one-to-one correspondence with part of the sensors, and an orthographic projection, on the base substrate, of each of the light transmitting hole lie in an orthographic projection, on the base substrate, of a sensor corresponding to the each light transmitting hole; and
an orthographic projection, on the base substrate, of each of the microlenses completely covers orthographic projections, on the base substrate, of a respective one of the light transmitting holes and at least two of the sensors, and the each microlens is configured to converge light rays reflected by a finger and then transmit the converged light rays to one of the at least two sensor that the each microlens covers through the respective one light transmitting hole that the each microlens covers.

16. A method for fabricating a fingerprint recognition module, comprising:
fabricating, on the first base substrate, an image sensing layer comprising a plurality of sensors;
providing a second base substrate;
fabricating, on the second base substrate, a light filter layer, a collimating optical layer comprising a plurality of light transmitting holes, and a light guiding layer comprising a plurality of microlenses; an orthographic projection, on the second base substrate, of each of the microlenses completely covers a respective one of the light transmitting holes; and
attaching the second base substrate provided with the light filter layer, the collimating optical layer, and the plurality of microlenses to incident sides of the plurality of sensors by optical adhesive; wherein the plurality of light transmitting holes are arranged in one-to-one correspondence with part of the sensors after attachment, an orthographic projection, on the second base substrate, of each of the light transmitting holes lies in an orthographic projection, on the second base substrate, of a sensor arranged corresponding to the each light transmitting hole, the orthographic projection, on the second base substrate, of each of the microlenses completely covers orthographic projections, on the second base substrate, of at least two of the sensors, and the each microlens is configured to converge light rays reflected by a finger and then transmit the converged light rays to one of the at least two sensors that the each microlens covers through the respective one light transmitting hole that the each microlens covers.

17. The method according to claim 16, wherein said fabricating, on the second base substrate, the light filter layer, the collimating optical layer, and the plurality of microlenses comprises:
fabricating, on the second base substrate, a first light transmitting layer, a second light shading layer, and a second light transmitting layer in sequence, wherein the first light transmitting layer is multiplexed as the light filter layer, a thickness, perpendicular to the second base substrate, of the second light transmitting layer is smaller than or equal to a focal length of each of the plurality of microlenses to be fabricated, and the second light shading layer comprises a plurality of second light transmitting holes;
fabricating the plurality of the microlenses on the second light transmitting layer, wherein the orthographic projection, on the second base substrate, of each of the microlenses completely covers orthographic projections, on the second base substrate, of a respective one of the second light transmitting holes and the at least two of the sensors; and
fabricating a first light shading layer on a side, facing away from the first light transmitting layer, of the second base substrate; wherein the first light shading layer comprises a plurality of first light transmitting holes which fully coincide with the plurality of second light transmitting holes in a direction perpendicular to the second base substrate, and the first light shading layer, the first light transmitting layer, the second light shading layer, and the second light transmitting layer constitute the collimating optical layer.

18. The method according to claim 16, wherein said fabricating, on the second base substrate, the light filter layer, the collimating optical layer, and the plurality of microlenses comprises:
sequentially fabricating, on the second base substrate, the light filter layer and a second light transmitting layer; wherein a sum of thicknesses, in a direction perpendicular to the second base substrate, of the second base substrate, the light filter layer, and the second light transmitting layer is smaller than or equal to a focal length of each of the plurality of microlenses to be fabricated;
fabricating the plurality of microlenses on the second light transmitting layer; wherein the orthographic projection, on the second base substrate, of each of the microlenses completely covers orthographic projections, on the second base substrate, of the respective one of the light transmitting holes comprised in a light shading layer to be fabricated and the at least two of the sensors; and
fabricating a second light shading layer, a first light transmitting layer, and a first light shading layer in sequence on a side, facing away from the light filter layer, of the second base substrate;
wherein the first light shading layer and the second light shading layer comprise the plurality of light transmitting holes which completely coincide in the direction perpendicular to the second base substrate, and the first light shading layer, the first light transmitting layer, the second light shading layer, and the second light transmitting layer constitute the collimating optical layer.

19. The method according to claim 16, wherein said fabricating, on the second base substrate, the light filter layer, the collimating optical layer, and the plurality of microlenses comprises:
fabricating, on the second base substrate, the light filter layer, a first light shading layer, a first light transmitting layer, a second light shading layer, a second light transmitting layer, and a plurality of microlenses in sequence;
wherein the first light shading layer and the second light shading layer comprise the plurality of light transmitting holes in a direction perpendicular to the second base substrate, and the first light shading layer, the first light transmitting layer, the second light shading layer, and the second light transmitting layer constitute the collimating optical layer; and
the orthographic projection, on the second base substrate, of each of the microlenses completely covers orthographic projections of the respective one of the light transmitting holes and the at least two of the sensors.

20. The method according to claim 17, after fabricating the second light transmitting layer, and before fabricating of the plurality of microlenses, further comprising:
fabricating a third light shading layer on the second light transmitting layer, wherein an orthographic projection, on the second base substrate, of the third light shading layer covers gaps between the microlenses and overlaps with edge areas of orthographic projections, on the second substrate, of the plurality of microlenses.
